(19) United States
(12) Patent Application Publication
(10) Pub. No.: US 2010/0269884 A1
(43) Pub. Date: Oct. 28, 2010

(54) SOLAR POWER GENERATING APPARATUS

(75) Inventor: Tai-Hui LIU, Hukou Shiang (TW)

Correspondence Address: LIU & LIU, 444 S. FLOWER STREET SUITE 1750, LOS ANGELES, CA, 90071, US

(73) Assignee: SOLAPOINT CORPORATION, Hukou Shiang (TW)

(21) Appl. No.: 12/765,664

(22) Filed: Apr. 22, 2010

(30) Foreign Application Priority Data
Apr. 23, 2009 (TW) 98206794

(51) Int. Cl. H01L 31/052; H01L 31/00

(52) U.S. Cl. 136/246; 136/259

(57) ABSTRACT

The present invention provides a solar power generating apparatus including a base and multiple power generating units connected in series. Each of the power generating units includes a heat dissipation plate separably connected to the base; a solar cell disposed on the heat dissipation plate; and a rectification device connected in parallel to the solar cell. When the heat dissipation plate of one of the power generating units is detached from the base, the others of the power generating units may continue to operate.

### CROSS REFERENCE TO RELATED APPLICATIONS

This application claims the right of priority based on Taiwan Patent Application No. 98206794 entitled “SOLAR POWER GENERATING APPARATUS” filed on Apr. 23, 2009, which is incorporated herein by reference and assigned to the assignee herein.

### FIELD OF THE INVENTION

The present invention relates to a solar power generating apparatus and in particular, to the solar power generating apparatus having a separable heat dissipation plate.

### BACKGROUND OF THE INVENTION

As shown in FIGS. 1A and 1B, a conventional solar power generating apparatus 1 consists of a frame 12 and multiple solar cell modules 14 electrically connected in series. Each of the solar cell modules 14 consists of a solar cell 141, a diode 142 and an insulation substrate 143. The solar cell 141 and the diode 142 of each solar cell modules 14 are connected and disposed on the corresponding insulation substrate 143. The frame 12 includes a metal bottom board 121. The solar cell modules 14 are disposed on the metal bottom board 121 of the frame 12.

However, when the conventional solar power generating apparatus 1 operates, the temperature where nears to the solar cell 141 is relatively high because light is gathered at the solar cells 141. The heat is conducted from the solar cells 141 to the metal bottom board 121 and diffused radially through the metal bottom board 121. The temperature at any point on the metal bottom board 121 rises when the point is closer to where the solar cell 141 is connected.

In general, the metal bottom board 121 is composed of aluminum. To improve the heat diffusion efficiency, the metal bottom board 121 may be composed of copper due to its higher heat diffusion efficiency. However, since copper is more expensive than aluminum, the cost of the metal bottom board 121 made of copper will be comparatively high. In addition, when one of the solar cells 141 in the solar power generating apparatus 1 is damaged or to be inspected for maintenance, the operation of the solar power generating apparatus 1 must stop in order to disassemble the specific solar cell 141 which are connected to the other solar cells 141 in series. Therefore, it leads an inconvenience that the solar power generating apparatus 1 cannot continue operation.

### SUMMARY OF THE INVENTION

In view of the problems mentioned above, the present invention is directed to provide a solar power generating apparatus having a separable heat dissipation plate to effectively diffuse heat around a solar cell and improve the heat diffusion efficiency. In addition, when one of the solar cells is maintained or inspected, the solar power generating apparatus needs no stop and still generates power. Therefore, the problems or deficiencies in the prior art can be solved.

To achieve the above-mentioned objectives, the solar power generating apparatus of the present invention includes a base and multiple power generating units connected in series. Each of the power generating units includes a heat dissipation plate separably connected to the base; a solar cell disposed on the heat dissipation plate; and a rectification device connected in parallel to the solar cell. When the heat dissipation plate of one of the power generating units is detached from the base, the others of the power generating units may continue to operate.

The following advantages may be achieved by using the technical features mentioned above:
1. The heat diffusion in terms of a local area around a heat source is improved to meet the requirement of heat diffusion. In addition, because it is a local improvement, the base does not need to be replaced entirely such that the cost can be decreased.
2. Each of the solar cells and each of the rectification devices can be modularized respectively such that the function of hot plugging can be achieved. In addition, when the apparatus is maintained or inspected, the apparatus does not need to stop such that the operation efficiency of the apparatus is improved.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute part of this specification. The drawings illustrate embodiments of the invention and, together with the description, serve to explain the principles of the invention.

FIG. 1A is a structural view of a conventional solar power generating apparatus.

FIG. 1B is a structural view of a conventional solar cell module.

FIG. 2 is a structural view of a solar power generating apparatus according to a first embodiment of the present invention.

FIG. 3 is a structural top view of a power generating unit according to a first embodiment of the present invention.

FIG. 4 is a circuit diagram of multiple power generating units.

FIG. 5A is a structural top view of the connection between a heat dissipation plate, a base and a solar cell according to a second embodiment of the present invention.

FIG. 5B is a structural side view of the connection between the heat dissipation plate, the base and the solar cell according to the second embodiment of the present invention.

FIG. 6A is a structural top view of the connection between a heat dissipation plate, a base and a solar cell according to a third embodiment of the present invention.

FIG. 6B is a structural side view of the connection between the heat dissipation plate, the base and the solar cell according to the third embodiment of the present invention.

FIG. 7A is a structural top view of the connection between a heat dissipation plate, a base and a solar cell according to a fourth embodiment of the present invention.

FIG. 7B is a structural side view of the connection between the heat dissipation plate, the base and the solar cell according to the fourth embodiment of the present invention.

FIG. 8A is a structural top view of the connection between a heat dissipation plate, a base and a solar cell according to a fifth embodiment of the present invention.

FIG. 8B is a structural side view according to the connection between the heat dissipation plate, the base and the solar cell of the fifth embodiment of the present invention.

FIG. 9A is a structural top view of the connection between a heat dissipation plate, a base and a solar element according to a sixth embodiment of the present invention.

FIG. 9B is a structural side view of the connection between the heat dissipation plate, the base and the solar element according to the sixth embodiment of the present invention.

FIG. 10A is a structural top view of the connection between a heat dissipation plate, a base and a solar element according to a seventh embodiment of the present invention.

FIG. 10B is a structural side view of the connection between the heat dissipation plate, the base and the solar element according to the seventh embodiment of the present invention.

FIG. 11A is a structural top view of the connection between a heat dissipation plate, a base and a solar element according to an eighth embodiment of the present invention.

FIG. 11B is a structural side view of the connection between the heat dissipation plate, the base and the solar element according to the eighth embodiment of the present invention.

### DETAILED DESCRIPTION OF THE INVENTION

The preferred embodiments of the present invention will now be described in greater details by referring to the drawings that accompany the present application. It should be noted that the features illustrated in the drawings are not necessarily drawn to scale. Descriptions of well-known components, materials, and process techniques are omitted so as to not unnecessarily obscure the embodiments of the invention. Any devices, components, materials, and steps described in the embodiments are only for illustration and not intended to limit the scope of the present invention.

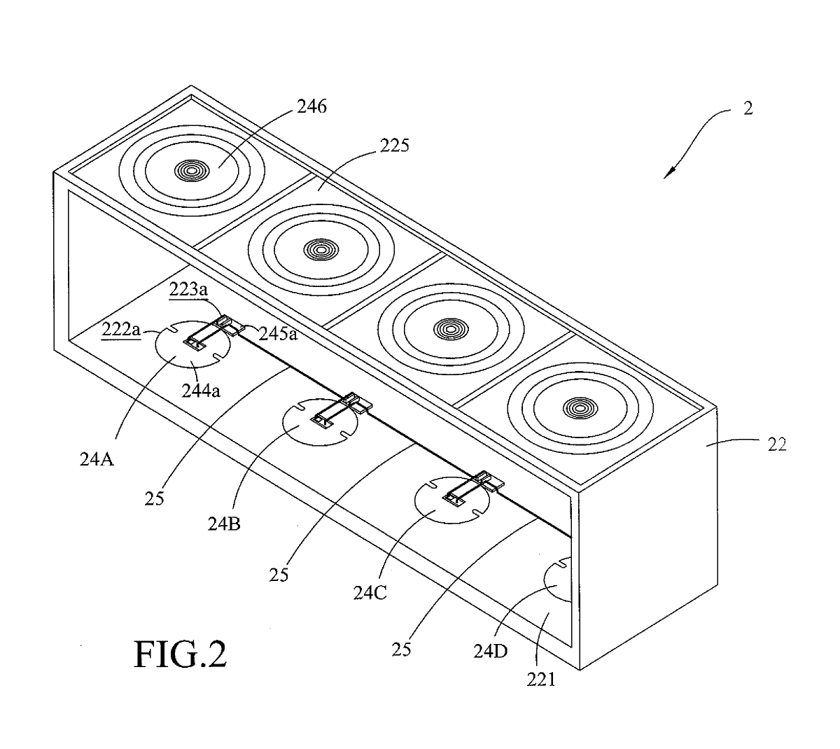

FIG. 2 is a structural view of a solar power generating apparatus 2 according to a first embodiment of the present invention. The solar power generating apparatus of the present invention includes a frame 22; multiple power generating units 24A, 24B, 24C [symbol] 24D disposed within the frame 22; a first conductive wire 25 connecting the multiple power generating units 24A-24D in series and being disposed on the base 221 of the frame 22; and multiple condensing elements 246 inserted in the top board 225 of the frame 22. The condensing elements 246 are corresponding to the power generating units 24A-24D, respectively.

Referring to FIG. 2, the frame 22 is a rectangular frame. An accommodating space is located at the interior of the frame 22. The frame 22 includes a base 221 and a top board 225 respectively disposed at the bottom and the top of the frame 22. The base 221 is composed of metal such as aluminum. The base 221 has multiple openings such as a first opening 222a and a second opening 223a. The first opening 222a and the second opening 223a are used for accommodating a heat dissipation plate 244a and a carrier 245a of the power generating unit 24A respectively. When the solar power generating apparatus 2 operates, the base 221 may contact the external environment to diffuse heat of the solar power generating apparatus 2.

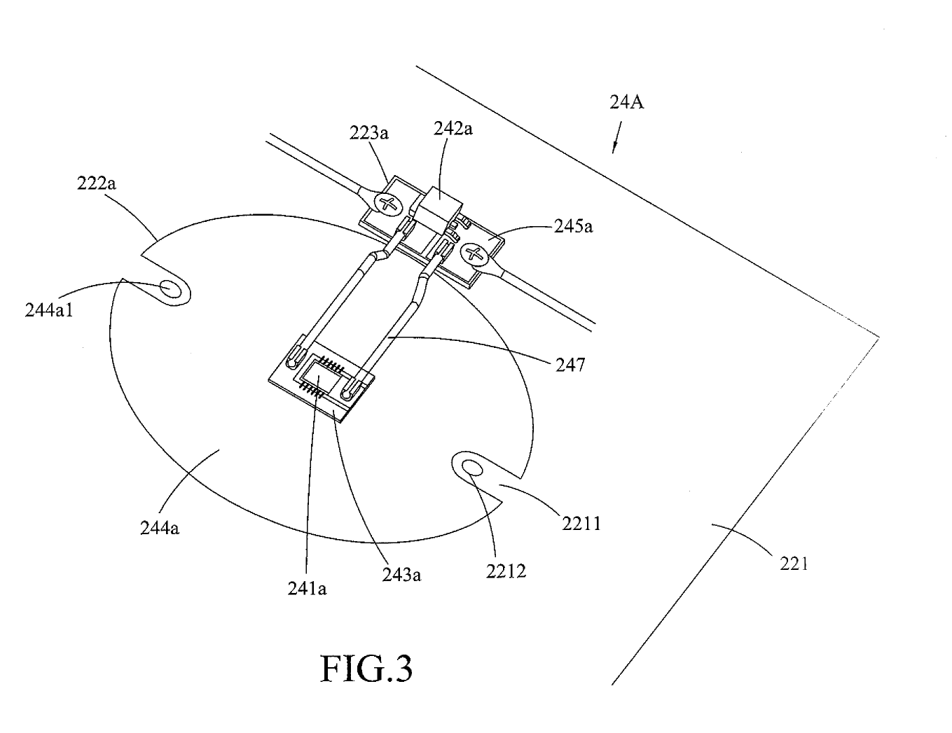

FIG. 3 is a structural top view of the power generating unit 24A according to a first embodiment of the present invention. The structures of the power generating units 24B-24D are similar to that of the power generating unit 24A. Referring to FIG. 3, the power generating unit 24A includes a solar cell 241a disposed on an insulation substrate 243a; the heat dissipation plate 244a carrying the insulation substrate 243a and being separably connected to the base 221; a rectification diode 242a disposed on the carrier 245a separably connected to the base 221; and multiple second conductive wires 247 used for electrically connecting the solar cell 241 a and the rectification diode 242a. Four power generating units 24A-24D are illustrated in the present embodiment but the number of the power generating units is not limited herein. The solar cell 241a may be a conventional element absorbing light and transferring light energy into electric energy. The solar cell 241a is disposed on the insulation substrate 243a. The insulation substrate 243a may be made of any adequate insulation material. The heat dissipation plate 244a is disposed in the first opening 222a of the base 221 and separably connected to the base 221. The heat dissipation plate 244a and the base 221 may be separably connected by means of insertion, lodging, locking or other adequate ways. For example, in a first embodiment of the present invention (referring to FIG. 3), multiple first protrusions 2211 of the base 221 are formed at the first opening 222a and toward the first opening 222a. Multiple holes 2212 are formed in the first protrusions 2211, respectively. Multiple second protrusions 244a1 are formed at an edge of the heat dissipation plate 244a and directed upwardly and perpendicularly. The second protrusions 244a1 may be lodged with the holes 2212 such that the base 221 and the heat dissipation plate 244a are separably connected. The heat dissipation plate 244a may be composed of the material such as copper of which the thermal conduction efficiency is higher than that of the material of the base 221. The rectification diode 242a may be a conventional PN junction diode having the function of rectifying such that the current in a specific direction from p-type area to n-type area can pass through the diode easily and the current against the direction cannot pass through the diode easily. The carrier 245a is disposed in the second opening 223a of the base 221 and separably connected to the base 221. The carrier 245a and the base 221 may be separably connected by means of insertion, lodging, locking or other ways. The connection between the carrier 245a and the base 221 may be referred to the connection between the base 221 and the heat dissipation plate 244a. The carrier 245a may be composed of the material such as copper of which the thermal conduction efficiency is higher than that of the material of the base 221. In addition, the carrier 245a may be composed of ceramics or aluminum. It should be noted that the carrier 245a is optional and in another embodiment, the rectification diode 242 may be disposed on the base 221 directly.

As shown in FIGS. 2 and 3, the solar power generating apparatus 2 is assembled through the following steps. First, the heat dissipation plate 244a and the carrier 245a are inserted in the first opening 222a and the second opening 223a of the base 221 of the frame 22 such that the heat dissipation plate 244a and the carrier 245a are separably connected to the base 221. The solar cell 241a is disposed on the insulation substrate 243a, the insulation substrate 243a is disposed on the heat dissipation plate 244a, and the rectification diode 242a is disposed on the carrier 245a. Next, the rectification diode 242a and the solar cell 241a on the insulation substrate 243a are electrically connected through the second conductive wires 247 such that the power generating unit 24A is assembled. According to the same assembling way, the power generating units 24B-D are assembled. Afterwards, the adjacent power generating units such as the power generating units 24A-B are electrically connected through the first conductive wire 25. In addition, the condensing elements 246 are disposed on the top surface of the frame 22. The condensing elements 246 are inserted in the top board 225. Each of the condensing elements 246 is a lens similar to a convex that may focus light on corresponding one of the solar cells. Accordingly, the assembly of the solar power generating apparatus 2 is completed.

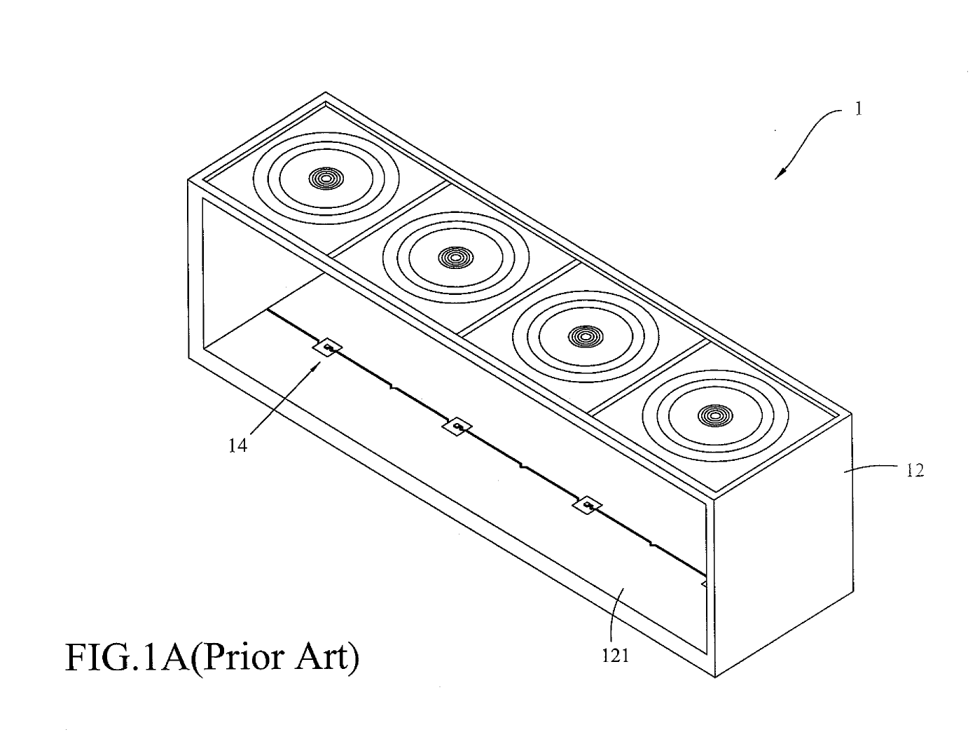

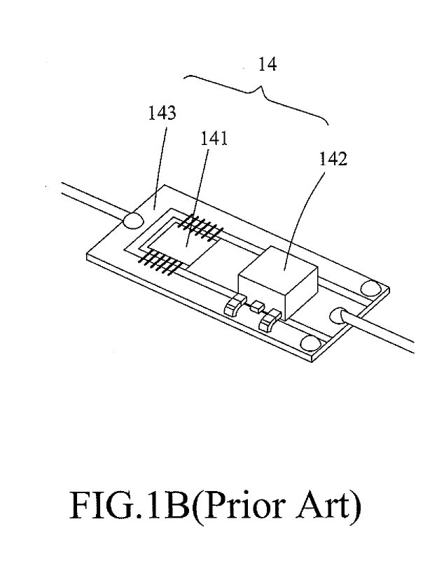

Referring to FIGS. 2 and 3, heat aggregated at the solar cell 241a is transferred to the heat dissipation plate 244a through the insulation substrate 243a. Preferably, the heat dissipation plate 244a may be made of the material having higher thermal conduction efficiency, such as copper, because the heat dissipation plate 244a carrying the solar cell 241a bears more heats. In comparison to the heat dissipation plate 244a, the base 221 is less close to the solar cell 241a, so the requirement for high thermal conduction efficiency of the base 221 is not severe and the base 221 may be made of the material such as aluminum. The density of aluminum is lower than that of copper and the cost of aluminum is relatively cheap. Therefore, compared to the conventional base 121 (shown in FIG. 1) completely made of copper, the design of separable connection between the base 221 made of aluminum and the heat dissipation plate 244a made of copper in the present invention may achieve reduction of the cost and improvement of the heat diffusion efficiency.

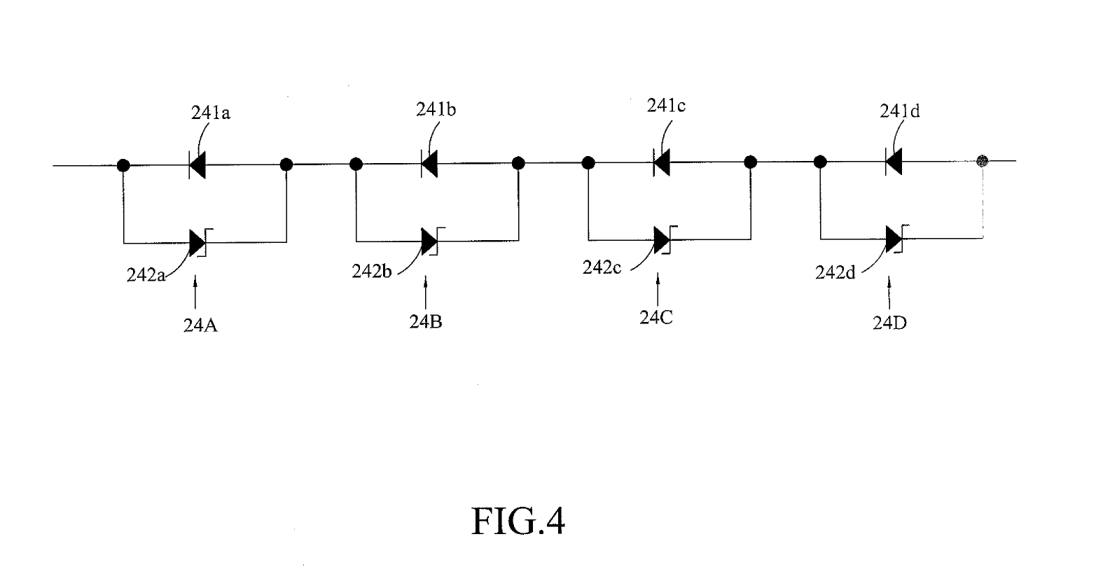

FIG. 4 is a circuit diagram of the multiple power generating units 24A-24D. Referring to FIG. 4, the solar cell 241 and the rectification diode 242 of each of the power generating units are connected in parallel and the multiple power generating units 24A-24D are connected in series. When the power generating units 24A-24D operate normally, each of the rectification diodes 242a-242d is biased reversely such that no current passes through the rectification diodes 242a-242d and all current passes through the solar cells 241a-241d. When the solar cell 241a of the power generating unit 24A is damaged or covered by cloud, the rectification diode 242a of the power generating unit 24A is biased forward such that a current path through the rectification diode 242a is formed, but the rectification diodes 242b-242d of the power generating units 24B-24D are still biased reversely, and thus current still passes through the solar cells 241b-241d of the power generating units 24B-24D. Accordingly, when the solar cell 241a is damaged or needs to be maintained, the solar cell 241a disposed on the heat dissipation plate 244a may be detached to be replaced at will and at the same time the solar cells 241b-241d of the power generating units 24B-24D can still operate normally with no influence from the solar cell 241a. Accordingly, the solar power generating apparatus 2 may be maintained or repaired without stopping.

FIGS. 5A and 5B are structural views of the connection between a heat dissipation plate 32, a base 31 and a solar cell 33 according to a second embodiment of the present invention. FIG. 5A is a structural top view of the connection between the heat dissipation plate 32, the base 31 and the solar cell 33. FIG. 5B is a structural side view of the connection between the heat dissipation plate 32, the base 31 and the solar cell 33. Referring to FIGS. 5A and 5B, in the second embodiment of the present invention, the heat dissipation plate 32 may be located below the base 31 and fixed to the base 31 by a part of the bolts 34. The solar cell 33 is fixed on the heat dissipation plate 32 by another part of the bolts 34. In the present embodiment, the connection between the solar cell 33, the base 31 and the heat dissipation plate 32 is simply disclosed, and the solar cell 33 and the rectification diode can be electrically connected through the second conductive wires 247 of the first embodiment (referring to FIG. 3), so it should not be described in detail herein. In addition, in the present embodiment, the heat dissipation plate 32 may be composed of ceramics.

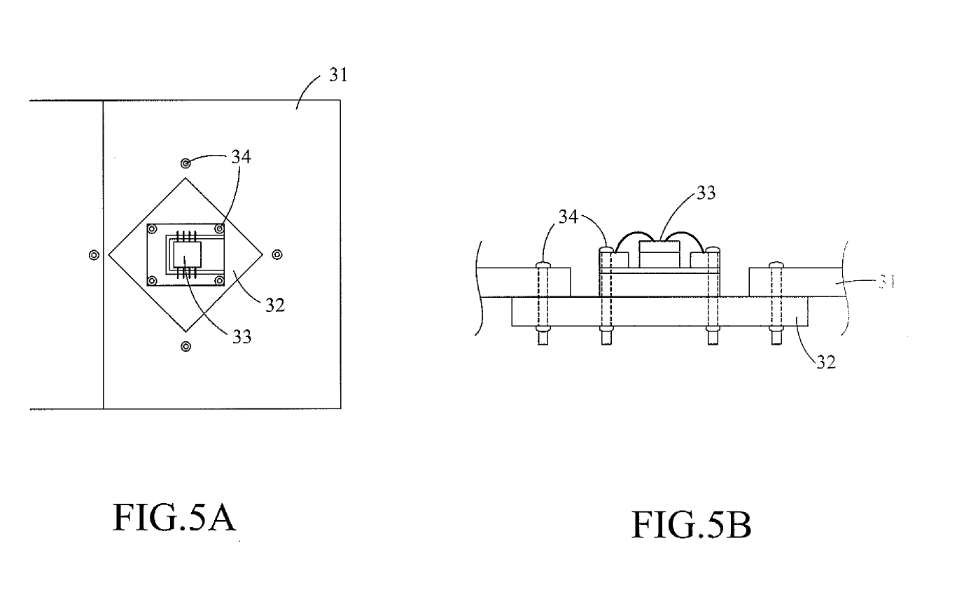

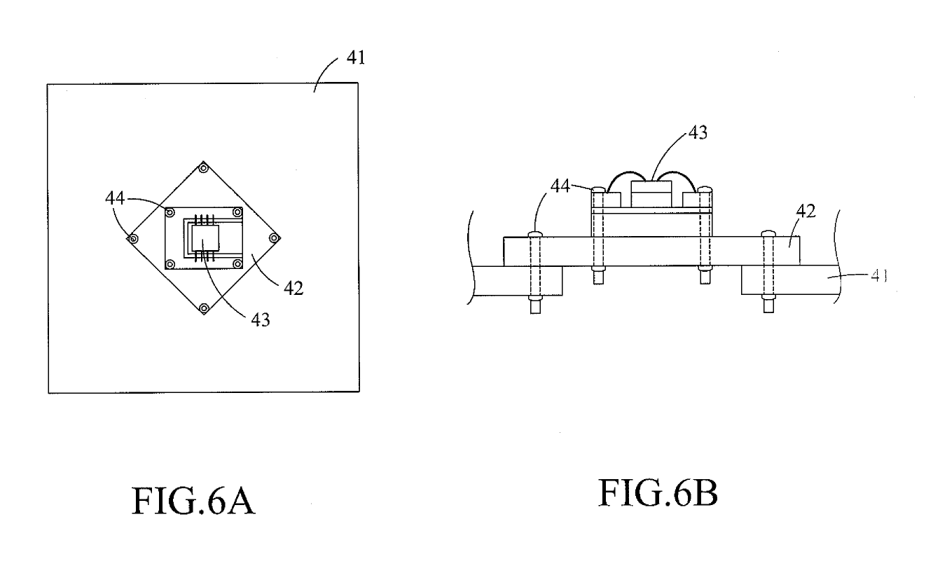

FIGS. 6A and 6B are structural views of the connection between a heat dissipation plate 42, a base 41 and a solar cell 43 according to a third embodiment of the present invention. FIG. 6A is a structural top view of the connection between the heat dissipation plate 42, the base 41 and the solar cell 43. FIG. 6B is a structural side view of the connection between the heat dissipation plate 42, the base 41 and the solar cell 43. The third embodiment of the present invention is similar to the second embodiment. The difference between the third and the second embodiments is that the heat dissipation plate 42 is located above the base 41. The heat dissipation plate 42 is also fixed to the base 41 by a part of the bolts 44.

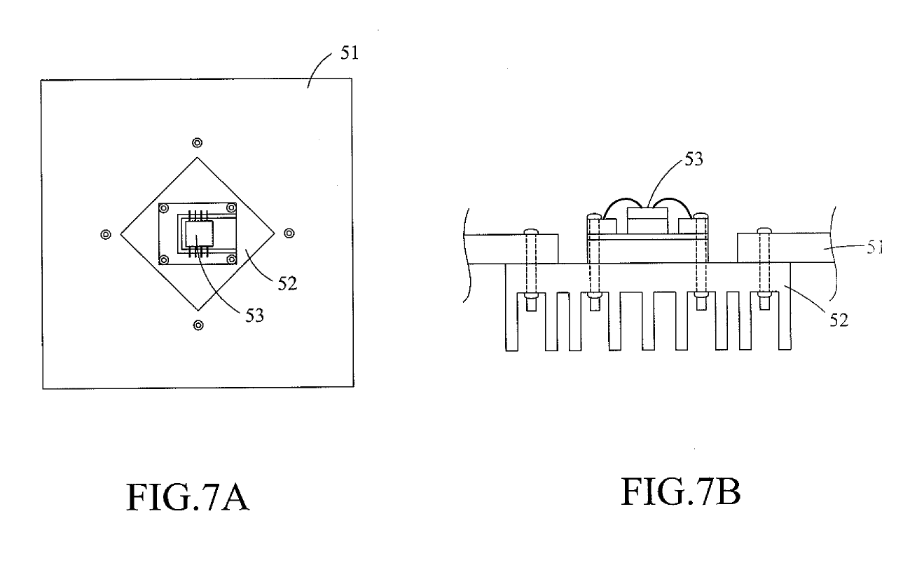

FIGS. 7A and 7B are structural views of the connection between a heat dissipation plate 52, a base 51 and a solar cell 53 according to a fourth embodiment of the present invention. FIG. 7A is a structural top view of the connection between the heat dissipation plate 52, the base 51 and the solar cell 53. FIG. 7B is a structural side view of the connection between the heat dissipation plate 52, the base 51 and the solar cell 53. The fourth embodiment of the present invention is similar to the second embodiment. The difference between the fourth and the second embodiments is that a fin-type heat dissipation structure may be made below the heat dissipation plate 52 to improve the heat diffusion efficiency.

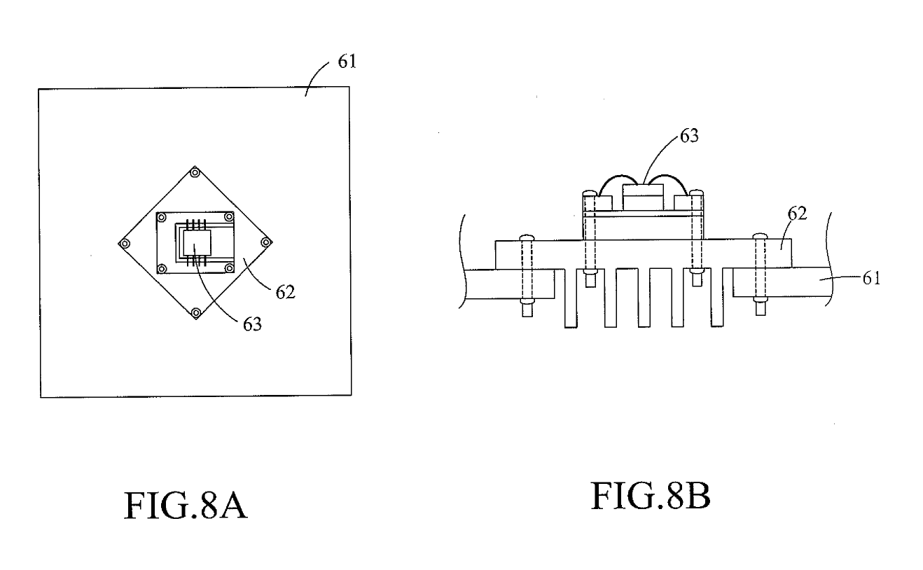

FIGS. 8A and 8B are structural views of the connection between a heat dissipation plate 62, a base 61 and a solar cell 63 according to a fifth embodiment of the present invention. FIG. 8A is a structural top view of the connection between the heat dissipation plate 62, the base 61 and the solar cell 63. FIG. 8B is a structural side view of the connection between the heat dissipation plate 62, the base 61 and the solar cell 63. The fifth embodiment of the present invention is similar to the third embodiment. The difference between the fifth and the third embodiments is that a fin-type heat dissipation structure may be made below the heat dissipation plate 62 to improve the heat diffusion efficiency.

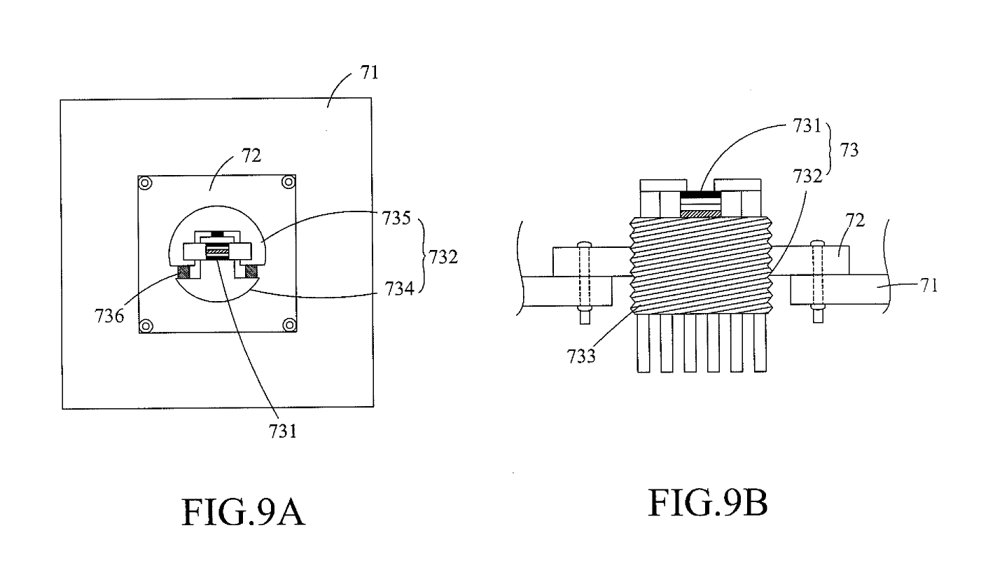

FIGS. 9A and 9B are structural views of the connection between a heat dissipation plate 72, a base 71 and a solar element 73 according to a sixth embodiment of the present invention. FIG. 9A is a structural top view of the connection between the heat dissipation plate 72, the base 71 and the solar element 73. FIG. 9B is a structural side view of the connection between the heat dissipation plate 72, the base 71 and the solar element 73. Referring to FIGS. 9A and 9B, the sixth embodiment of the present invention is similar to the third embodiment. The difference between the sixth and the third embodiments is that the present embodiment includes a solar element 73 including a solar cell 731 and a heat dissipation foundation 732 carrying the solar cell 731. The heat dissipation foundation 732 includes a first portion 734 and a second portion 735 (referring to FIG. 9A). The first portion 734 and the second portion 735 are connected through multiple connection pads 736 and insulated from each other. The solar cell 731 is disposed on the second portion 735 of the heat dissipation foundation 732. Each of the connection pads 736 may be composed of any adequate insulation material such as ceramics or Teflon (polytetrafluoroethylene) or FR4 composite material used in a printed circuit board in general and composed of resin, glass fiber and inorganic filler. In the present embodiment, the heat dissipation foundation 732 is cylinder-shaped and a female thread 733 is disposed at the outer surface of the heat dissipation foundation 732. A fin-type heat dissipation structure may be made below the heat dissipation foundation 732. The heat dissipation foundation 732 is connected to the heat dissipation plate 72 by means of screwing. It should be noted that the number and the shape of the heat dissipation foundations 732 may be changed according to the requirement and is not limited in the present invention. The description of the structure of the solar element 73 of the present embodiment can be referred to Taiwan patent application Nos. 97135344 and 97136808.

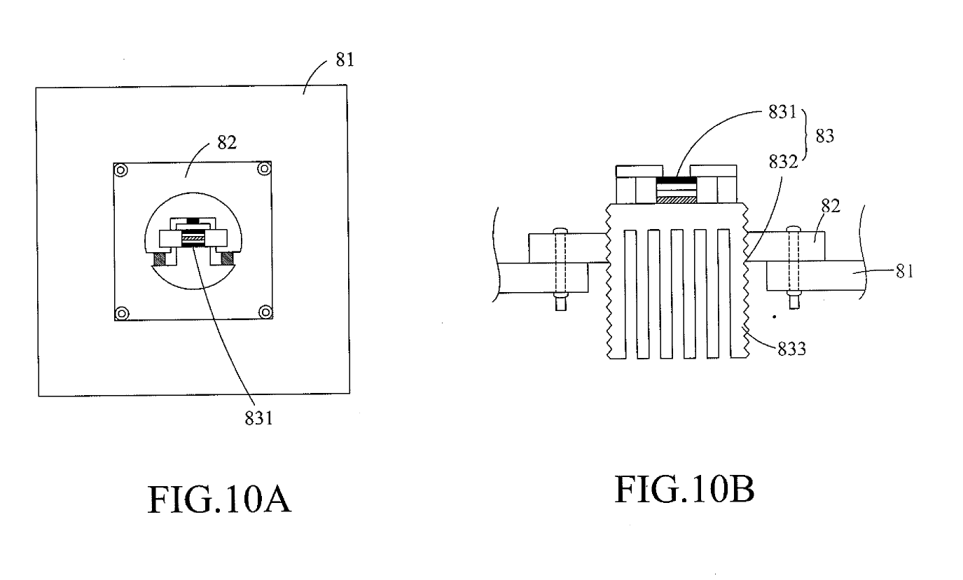

FIGS. 10A and 10B are structural views of the connection between a heat dissipation plate 82, a base 81 and a solar element 83 according to a seventh embodiment of the present invention. FIG. 10A is a structural top view of the connection between the heat dissipation plate 82, the base 81 and the solar element 83. FIG. 10B is a structural side view of the connection between the heat dissipation plate 82, the base 81 and the solar element 83. Referring to FIGS. 10A and 10B, the seventh embodiment of the present invention is similar to the sixth embodiment. The difference between the seventh and the sixth embodiments is that in the present embodiment, the heat dissipation foundation 832 has a longer fin-type heat dissipation structure. A female thread 833 is disposed at the outer surface of the fin-type heat dissipation structure. The fin-type heat dissipation structure is connected to the heat dissipation plate 82 by means of screwing.

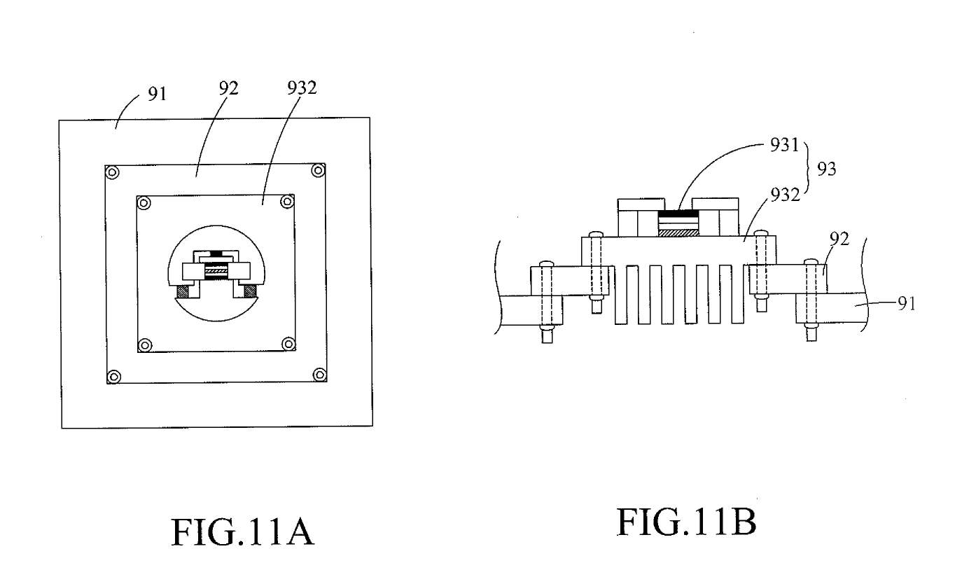

FIGS. 11A and 11B are structural views of the connection between a heat dissipation plate 92, a base 91 and a solar element 93 according to an eighth embodiment of the present invention. FIG. 11A is a structural top view of the connection between the heat dissipation plate 92, the base 91 and the solar element 93. FIG. 11B is a structural side view of the connection between the heat dissipation plate 92, the base 91 and the solar element 93. Referring FIGS. 11A and 11B, the eighth embodiment of the present invention is similar to the seventh embodiment. The difference between the eighth and the seventh embodiments is the structure of the heat dissipation foundation 932 of the solar element 93. In the present embodiment, the solar element 93 includes a solar cell 931 and a heat dissipation foundation 932 carrying the solar cell 931. The heat dissipation foundation 932 is disposed on the heat dissipation plate 92 and connected to the heat dissipation plate 92 by means of screwing. A fin-type heat dissipation structure is made below the heat dissipation foundation 932 to improve the heat diffusion efficiency.

The heat diffusion efficiency of the conventional solar power generating apparatus is relatively bad. In the conventional art, if the metal bottom board is made of the material of which the thermal conduction efficiency is relatively high, the cost is inevitable to increase. If the material is selected from copper to replace aluminum, the weight of the metal bottom board also increases. In addition, when the solar cells of the conventional solar power generating apparatus are maintained or inspected, the conventional solar power generating apparatus needs to stop and disassembly of the solar cells is not easy. In the present invention, the separable heat dissipation plate where the solar cell is disposed is used and only the heat dissipation plate is made of the material of which the thermal conduction efficiency is relatively high. Therefore, heat around the solar cell may be diffused efficiently and when the solar cell is damaged or malfunctions, the solar power generating apparatus of the present invention may be maintained or repaired without stopping. Accordingly, the deficiencies in the conventional art are efficiently solved.

Although the invention illustrated herein is embodied in above examples, it is not intended to limit the invention. The structural changes and modifications belong to the protective scope without departing from the aim and the scope of the invention. The scope of claims as defined in the present invention can refer to the following claims.

1. A solar power generating apparatus comprising :
a base; and
multiple power generating units connected in series, wherein each of the power generating units comprises:
a heat dissipation plate separably connected to the base;
a solar cell disposed on the heat dissipation plate; and
a rectification device connected to the solar cell in parallel, wherein when the heat dissipation plate of one of the power generating units is detached from the base, the others of the power generating units are adapted to continuing operation.

2. The solar power generating apparatus as claimed in claim 1, wherein the base further comprises multiple first openings used for accommodating the heat dissipation plates.

3. The solar power generating apparatus as claimed in claim 1, further comprising multiple condensing elements connected to the base, wherein the condensing elements focus light on the solar cells.

4. The solar power generating apparatus as claimed in claim 1, wherein each of the power generating units further comprises a carrier separably connected to the base, and the rectification device of each of the power generating units is disposed on the corresponding carrier.

5. The solar power generating apparatus as claimed in claim 4, wherein the base further comprises multiple second openings used for accommodating the carriers.

6. The solar power generating apparatus as claimed in claim 1, wherein the density of the material of the base is lower than the density of the material of the heat dissipation plates.

7. The solar power generating apparatus as claimed in claim 6, wherein the base is made of aluminum and the heat dissipation plates are made of copper.

8. The solar power generating apparatus as claimed in claim 2, wherein the base has a hole adjacent to one of the first openings, one of the heat dissipation plates has a second protrusion disposed at an edge of the corresponding heat dissipation plate, and the second protrusion is directed upwardly and perpendicularly and lodged with the hole.

9. The solar power generating apparatus as claimed in claim 8, wherein the base has a first protrusion toward the first opening to which the hole is adjacent, and the hole is formed in the first protrusion.
